(19) United States
(12) Patent Application Publication
(10) Pub. No.: US 2019/0256978 A1
(43) Pub. Date: Aug. 22, 2019

(54) PLASMA PROCESSING APPARATUS AND PLASMA PROCESSING METHOD

(71) Applicant: Samsung Display Co., Ltd., Yongin-si (KR)

(72) Inventors: Yong-Suk LEE, Suwon-si (KR); Suk-Won JUNG, Seoul (KR); Myung-Soo HUH, Suwon-si (KR); Mi-Ra AN, Suwon-si (KR)

(21) Appl. No.: 16/404,223

(22) Filed: May 6, 2019

Related U.S. Application Data
(62) Division of application No. 14/445,951, filed on Jul. 29, 2014.

(30) Foreign Application Priority Data
Oct. 23, 2013 (KR) 10-2013-0126615

(51) Int. Cl. C23C 16/46; H01J 37/32; C23C 16/458; C23C 16/34; C23C 16/40; C23C 16/52; C23C 16/509

(52) U.S. Cl. CPC C23C 16/46; H01J 37/32165; H01J 37/32091; C23C 16/4586; H01L 21/67109; C23C 16/401; C23C 16/52; C23C 16/509; C23C 16/345

(57) ABSTRACT

A plasma processing apparatus including: a chamber configured to provide a space for processing a substrate; a substrate stage configured to support the substrate within the chamber and including a first electrode, the first electrode configured to receive a first radio frequency signal; a second electrode disposed on an upper portion of the chamber to face the first electrode, the second electrode configured to receive a second radio frequency signal; a gas supply unit configured to supply a process gas onto the substrate within the chamber; and a thermal control unit configured to circulate a heat transfer medium through a first fluid passage provided in the first electrode and a second fluid passage provided in the second electrode to maintain the first and second electrodes at the same temperature.

### CROSS-REFERENCE TO RELATED APPLICATION

This application is a divisional of U.S. application Ser. No. 14/445,951, filed on Jul. 29, 2014, and claims priority from and the benefit of Korean Patent Application No. 2013-0126615, filed on Oct. 23, 2013, which are hereby incorporated by reference for all purposes as if fully set forth herein.

### BACKGROUND

### Field

Exemplary embodiments of the present invention relate to a plasma processing apparatus and a plasma processing method. More particularly, exemplary embodiments of the present invention relate to a plasma processing apparatus for performing a plasma deposition process and a plasma processing method using the same.

### Discussion of the Background

In manufacturing a flat panel display (FPD), such as an organic light emitting display (OLED) device, a plasma processing apparatus may be used to generate plasma to form a thin layer on a substrate.

In the plasma processing apparatus, because an upper electrode is exposed to plasma, and a radio frequency power for plasma generation is applied to the upper electrode, the temperature of the upper electrode may be increased more than the temperature of a lower electrode such that it may be difficult to maintain the upper electrode at a desired temperature.

Accordingly, a temperature difference between the upper electrode and the lower electrode may cause a temperature deviation of the substrate within a chamber. Thus, a control time for controlling the temperature thereof may be undesirably increased, resulting in reduced productivity.

The above information disclosed in this Background section is only for enhancement of understanding of the background of the invention and, therefore, it may contain information that does not constitute prior art.

### SUMMARY

Exemplary embodiments of the present invention provide a plasma processing apparatus capable of improving productivity.

Exemplary embodiments of the present invention also provide a plasma processing method using the plasma processing apparatus.

Additional features of the invention will be set forth in the description which follows, and in part will become apparent from the description, or may be learned from practice of the invention.

An exemplary embodiment of the present invention discloses a plasma processing apparatus including: a chamber configured to provide a space for processing a substrate; a substrate stage configured to support the substrate within the chamber and including a first electrode, the first electrode configured to receive a first radio frequency signal; a second electrode disposed on an upper portion of the chamber to face the first electrode, the second electrode configured to receive a second radio frequency signal; a gas supply unit configured to supply a process gas onto the substrate within the chamber; and a thermal control unit configured to circulate a heat transfer medium through a first fluid passage disposed in the first electrode and a second fluid passage disposed in the second electrode to maintain the first and second electrodes at the same temperature.

An exemplary embodiment of the present invention also discloses a plasma processing method including loading a substrate into a chamber of a plasma processing apparatus, the plasma processing apparatus including the chamber, a substrate stage configured to support the substrate and including a first electrode and a second electrode located on an upper portion of the chamber and facing the first electrode. A process gas is then introduced onto the substrate within the chamber. First and second radio frequency signals are applied to the first and second electrodes respectively to perform a plasma process on the substrate. The first and second electrodes are maintained at the same temperature.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view illustrating a plasma processing apparatus according to an exemplary embodiment of the present invention.

FIG. 2 is a block diagram illustrating a thermal control unit in FIG. 1.

FIG. 3 is a plan view illustrating a second electrode in FIG. 2.

FIG. 4 is a flow chart illustrating a plasma processing method according to an exemplary embodiment of the present invention.

FIGS. 5 to 10 are cross-sectional views illustrating an organic light emitting display device according to an exemplary embodiment of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the sizes and relative sizes of layers and regions may be exaggerated for clarity.

It will be understood that when an element or layer is referred to as being “on,” “connected to”, or “coupled to” another element or layer, it can be directly on, connected to, or coupled to the other element or layer, or intervening elements or layers may be present. In contrast, when an element is referred to as being “directly on,” “directly connected to”, or “directly coupled to” another element or layer, there are no intervening elements or layers present. Like numerals refer to like elements throughout. As used herein, the term “and/or” includes any and all combinations of one or more of the associated listed items. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be explained in detail with reference to the accompanying drawings.

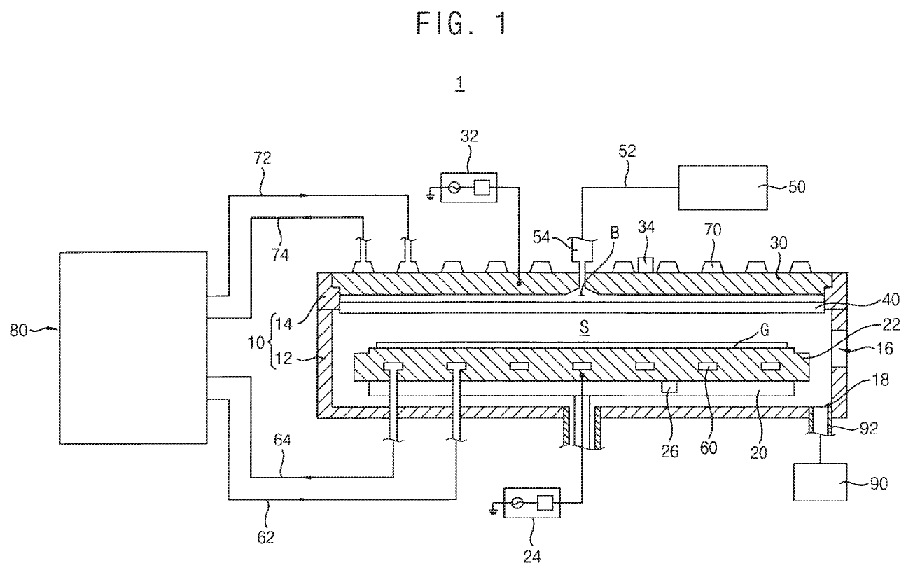

Referring to FIGS. 1 to 3, a plasma processing apparatus 1 may include a chamber 10, a substrate stage 20 having a first electrode 22, a second electrode 30, a gas supply unit having a gas distribution plate 40, and a thermal control unit 80.

The plasma processing apparatus may be an apparatus for performing a plasma enhanced chemical vapor deposition process (PECVD). The chamber 10 may provide a sealed processing space S for performing a plasma process on a substrate G. For example, the chamber 10 may include a lower chamber 12 and an upper chamber 14 that are combined with each other to define the space S for a deposition process.

A gate 16 for opening and closing a loading/unloading port of the substrate G may be installed in a sidewall of the lower chamber 12. The gate 16 may be selectively opened or closed by a gate valve (not illustrated). An exhaust valve (not illustrated) may be installed in a lower portion of the lower chamber 12 and connected to an exhausting portion 90 through an exhaust tube 92. The exhausting portion 90 may include a vacuum pump, such as turbo-molecular pump, to control the pressure of the chamber so that the processing space within the chamber 10 may be depressurized to a desire vacuum level.

The substrate stage 20 may be disposed in the lower chamber 12 to support the substrate. For example, the substrate stage 20 may be a susceptor for supporting the substrate G and the first electrode 22. The first electrode 22 may be supported such that the first electrode 22 is movable in upward and downward directions.

The substrate G may be supported on an upper surface of the first electrode 22. A focus ring (not illustrated) may be disposed on the first electrode 22 to surround the substrate G. The first electrode 22 may have a diameter greater than a diameter of the substrate G.

The second electrode 30 may be provided as an upper electrode in the upper chamber 14. The second electrode 30 may constitute either all or part of the upper portion of the chamber.

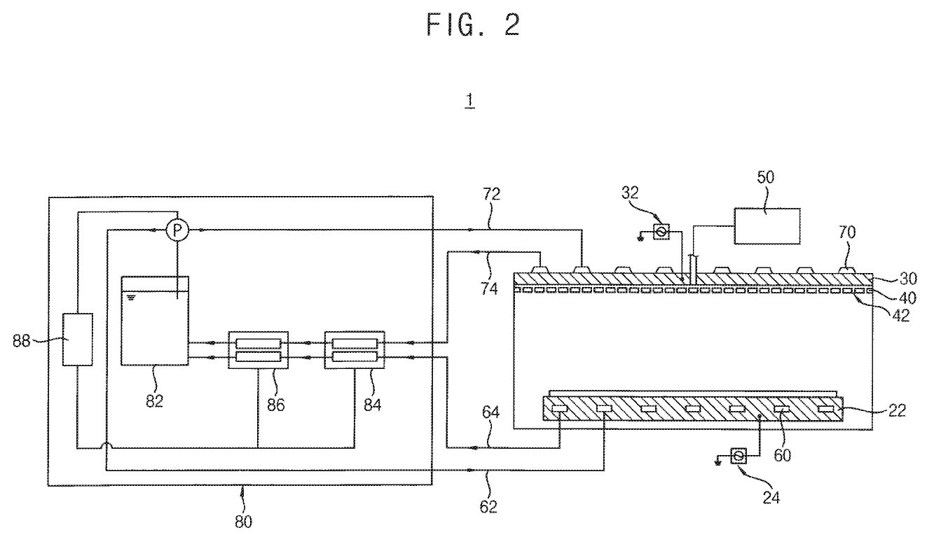

The gas supply unit may include the gas distribution plate 40 which is provided in an upper portion of the chamber 10 and has injection holes 42 for spraying the process gas, as shown in FIG. 2. The second electrode 30 may be disposed on the gas distribution plate 40 such that a buffer space B is formed between the second electrode 30 and the gas distribution plate 40.

A gas supply tube 54 for introducing the process gas may be connected to the buffer space B through the middle portion of the second electrode 30. Accordingly, the process gas may be supplied to the buffer space B from a gas supply source 50 through the gas supply tube 54, and then, the process gas may be sprayed onto the substrate G by the gas distribution plate 40.

The plasma processing apparatus 1 may further include a first radio frequency power supply unit 24 for applying a first radio frequency signal to the first electrode 22, and a second radio frequency power supply unit 32 for applying a second radio frequency signal to the second electrode 30. The first radio frequency power supply unit 24 may include a first radio power source and a first impedance matching circuit. The second radio frequency power supply unit 32 may include a second radio power source and a second impedance matching circuit.

The plasma processing apparatus 1 may include a control unit (not illustrated) for controlling the first and second radio frequency power supplies 24 and 32. The control unit, which includes a microcomputer and various interface circuits, may control an operation of the plasma processing apparatus based on programs and recipe information stored in an external or internal memory.

Each of the first and second radio frequency signals may include a radio frequency power having a pre-selected frequency (for example, 13.56 MHz). The first and second radio frequency signals respectively applied to the lower electrode 22 and the upper electrode 30 may have a same phase or may be offset by a pre-selected phase difference.

Accordingly, after the substrate G is loaded on the first electrode 22, a process gas may be supplied into the chamber 10 from the gas distribution plate 40, and a radio frequency power may be applied to the second electrode 30 by the second radio frequency power supply to generate plasma from the process gas in the processing space S within the chamber 10. Additionally, a radio frequency power may be applied to the first electrode 22 by the first radio frequency power supply to induce movement of charged particles of plasma toward the substrate G. Thus, a target layer may be deposited on the substrate G. The substrate G, including the layer formed thereon, may be unloaded from the chamber 10, and then, new substrate G may be loaded into the chamber 10 to perform a deposition process.

The thermal control unit 80 may circulate a heat transfer medium through a first fluid passage 60 provided in the first electrode 22 and a second fluid passage 70 provided in the second electrode 30 to maintain the first and second electrodes 22 and 30 at the same temperature.

As illustrated in FIG. 1, the first fluid passage 60 may be provided in the first electrode 22 such that the heat transfer medium flows through the first fluid passage 60. The first fluid passage 60 may have a circular or serpentine shape in the first electrode 22. The first fluid passage 60 may include a first supply line 62 and a first recovery line 64 to constitute a part of a circulation line of the thermal control unit. Accordingly, the heat transfer medium may be circulated through the first fluid passage 60 to control the temperature of the first electrode 22 and the substrate G on the first electrode 22.

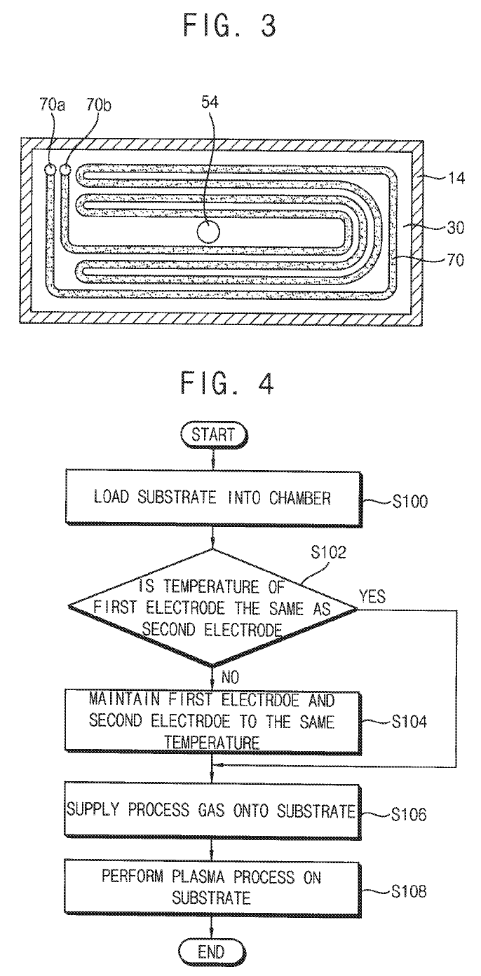

As illustrated in FIG. 3, the second fluid passage 70 may be disposed on an outer surface of the second electrode 30 such that the heat transfer medium flows through the second fluid passage 70. The second fluid passage 70 may make contact with the outer surface of the second electrode 30, and may have a serpentine shape. Alternatively, the second fluid passage 70 may have an elliptical shape. The second fluid passage 70 may penetrate the second electrode 30. Both end portions 70a and 70b of the second fluid passage 70 may be connected to a second supply line 72 and a second recovery line 74, respectively, to constitute a part of the circulation of the thermal control unit 80. Accordingly, the heat transfer medium may be circulated through the second fluid passage 70 to control the temperatures of the second electrode 30 and the gas distribution plate 40 adjacent to the second electrode 30.

In addition, a first temperature sensor 26 may be provided in the first electrode 22 to detect the temperature of the first electrode 22, and a second temperature sensor 34 may be provided in the second electrode 30 to detect the temperature of the second electrode 30. The first and second temperature sensors 26 and 34 may be in communication with the control unit of the plasma processing apparatus 1.

As illustrated in FIG. 2, the thermal control unit 80 may include the circulation line having the first fluid passage 60 and the second fluid passage 70, a heat exchanger 84 provided in the circulation line to transfer heat from the heat transfer medium exhausted from the first and second fluid passages 60 and 70, a heater 86 provided in the circulation line and arranged adjacent to the heat exchanger 84 to heat the heat transfer medium, a tank 82 connected to the first fluid passage 60 and the second fluid passage 70 to supply the heat transfer medium, and a temperature controller 88. For example, the heat transfer medium may include fluorine-based liquid, ethylene glycol, etc.

The temperature controller 88 may be in communication with the heat exchanger 84 to control a cooling operation of the heat exchanger 84. The temperature controller 88 may be in communication with the heater 86 and a pump P of the tank 82, to control operations thereof. The temperature controller 88 may be in communication with the control unit of the plasma processing apparatus, to control an operation of the temperature control unit based on information from the control unit.

For example, the temperature controller 88 may control the heat exchanger 84 to cool the heat transfer medium such that the first and second electrodes 22 and 30 may be maintained at a temperature under 100° C., for example, within a range of 60 to 85° C. The temperature controller 88 may control the heater 86 to heat the heat transfer medium such that the first and second electrodes 22 and 30 may be maintained in a temperature range of 60 to 85° C.

In this exemplary embodiment, the thermal control unit 80 may include at least one heat exchanger and at least one heater. However, the number of heat exchangers and heaters are not limited thereto. Accordingly, the thermal control unit 80 may heat or cool at least one of the first electrode 22 and the second electrode 30.

As mentioned above, the thermal control unit may circulate the heat transfer medium through the first and second fluid passages 60 and 70 to control the temperature of the first electrode 22 and the second electrode 30. Accordingly, the first electrode 22 and the second electrode 30 may be maintained at the same temperature to control the substrate G to a desired temperature during a plasma process.

Hereinafter, a method of processing a substrate using the plasma processing apparatus in FIG. 1 will be explained.

FIG. 4 is a flow chart illustrating a plasma processing method in accordance with exemplary embodiments.

Referring to FIGS. 1, 2 and 4, a substrate G may be loaded into a plasma chamber 10 (S100).

First, the substrate G may be loaded on a first electrode 22 within the chamber 10 through a gate 112. The substrate G may be a substrate for display panel. The substrate G may include a driving circuit portion and an organic light emitting display element formed thereon. The substrate G may include a glass substrate or a flexible substrate.

The substrate G may be a substrate for a display panel. The substrate G may include a driving circuit portion and an organic light emitting display element formed thereon. The substrate G may include a glass substrate or a flexible substrate. For example, the substrate may include polyimide, polyethylene terephthalate, polycarbonate, polyarylate, polyetheretherketone, etc.

Then, after the temperature of the first electrode 22 is compared with the temperature of a second electrode 30 (S102), the first and second electrodes 22 and 30 may be controlled to be maintained at the same temperature (S104).

Before performing a plasma process on the substrate G, the temperature of the first and second electrodes 22 and 30 may be detected by a first temperature sensor 26 and a second temperature sensor 34, respectively. When the temperature of the first electrode 22 is different from the temperature of the second electrode 30, the first and second electrodes 22 and 30 may be adjusted to the same temperature.

For example, when the temperature of the first and second electrodes 22 and 30 is lower than a pre-selected temperature, a heat transfer medium may be heated by a heater 86 of a thermal control unit and circulated through first and second fluid passages 60 and 70, to thereby adjust the first and second electrodes 22 and 30 to the same pre-selected temperature. For example, the first and second electrodes 22 and 30 may be maintained at a temperature of less than 100° C., for example, a temperature of 60 to 85° C.

The temperature of the second electrode 30 and a gas distribution plate 40 may be increased by the plasma process previously performed. For example, the second electrode 30 may be heated to a temperature greater than 100° C. When the temperature of the second electrode 30 is higher than the temperature of the first electrode 22, the heat transfer medium may be cooled by a heat exchanger and circulated through the first and second fluid passages 60 and 70 to adjust the first and second electrodes 22 and 30 to a pre-selected temperature. For example, the first and second electrodes 22 and 30 may be maintained at a temperature of less than 100° C., for example, of 60 to 85° C.

Then, a process gas from a gas supply source 50 may be introduced into the chamber 10 and supplied to the substrate G by a gas supply unit (S106). The pressure of the chamber 10 may be adjusted to a pre-selected value by an exhausting portion 90.

The gas supply unit may supply process gas for forming an inorganic layer on the substrate G. For example, the inorganic layer may include silicon oxide, silicon nitride, etc. The gas supply unit may supply a precursor, an oxygen gas, a nitrogen gas, etc., for forming silicon compound. Then, first and second radio frequency signals may be applied to the first electrode 22 and the second electrode 30, respectively, to perform a plasma process on the substrate G (S108).

A first radio frequency power supply 24 may supply a first radio frequency signal for bias control to the first electrode 22, and a second radio frequency power supply 32 may supply a second radio frequency signal for plasma generation to the second electrode 30, in response to a control signal of a control unit.

The process gas may be converted into plasma between the first electrode 22 and the second electrode 30 to be deposited to form an inorganic layer on the substrate G. The inorganic layer may be at least one inorganic layer of a thin film encapsulation (TFE) layer which covers the organic light emitting display element on the substrate G.

The substrate G, including the inorganic layer formed thereon, may be unloaded from the chamber 10, and then transferred to an organic deposition apparatus for performing an organic layer deposition process.

In exemplary embodiments, when or after a plasma process is performed on the substrate G, the temperature of the first electrode 22 and the second electrode 30 may be detected. When the temperature of the first electrode 22 is detected to be different from the temperature of the second electrode 30, the first and second electrodes 22 and 30 may be adjusted to the same temperature.

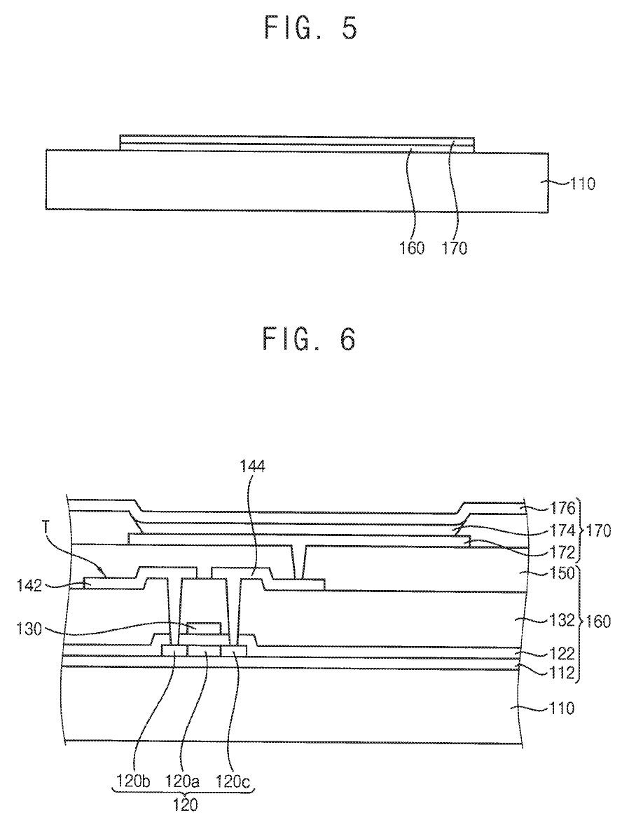

Hereinafter, a method of manufacturing an organic light emitting display device using the plasma processing apparatus in FIG. 1 will be explained, with reference to FIGS. 5-10.

Referring to FIGS. 5 and 6, a display panel of an organic light emitting display device may include a driving circuit portion 160 and an organic light emitting display element 170 disposed on a base substrate 110.

The driving circuit portion 160 may include at least two thin film transistors and at least one capacitor. The thin film transistors may include a switching transistor T and a driving transistor (not illustrated).

The organic light emitting display element 170 may include a first electrode (hole injection electrode/anode) 172, an organic light emitting layer 174, and a second electrode (electron injection electrode/cathode) 176.

The base substrate 110 may include a flexible substrate. The base substrate 110 may include a transparent insulating material capable of supporting conductive patterns and layers stacked on each other. A buffer layer 112 may be provided on the base substrate 110.

The switching transistor T may include a semiconductor pattern 120, a gate electrode 130, a source electrode 142, and a drain electrode 144. The semiconductor pattern 120 is divided into a channel region 120a, a source region 120b, and a drain region 120c, where the source region 120b is connected to the source electrode 142, and the drain region is connected to the drain electrode 144. A gate insulation layer 122 may be interposed between the semiconductor pattern 120 and the gate electrode 140. The transistor T may be a thin film transistor having a top-gate structure, as illustrated in FIG. 6. Alternatively, the transistor may be a thin film transistor T having a bottom-gate structure.

An insulation interlayer 132 may be provided on the gate insulation layer 122 to cover the gate electrode 130. The insulation interlayer may have a multi-layered structure of inorganic layers. The inorganic layer may include silicon oxide, silicon nitride, silicon oxynitride, silicon carbonitride, etc.

A protection layer 150 may cover the source electrode 142 and the drain electrode 144, and may have a substantially flat upper surface. The protection layer 150 may have an opening which exposes the drain electrode 144.

A first electrode 172 may be provided on the protection layer 150 to be connected to the drain electrode 144. A pixel defining layer (not shown) may be provided on the protection layer 150 to expose the first electrode 172. The organic light emitting structure 174 and the second electrode 176 may be sequentially provided on the first electrode 172.

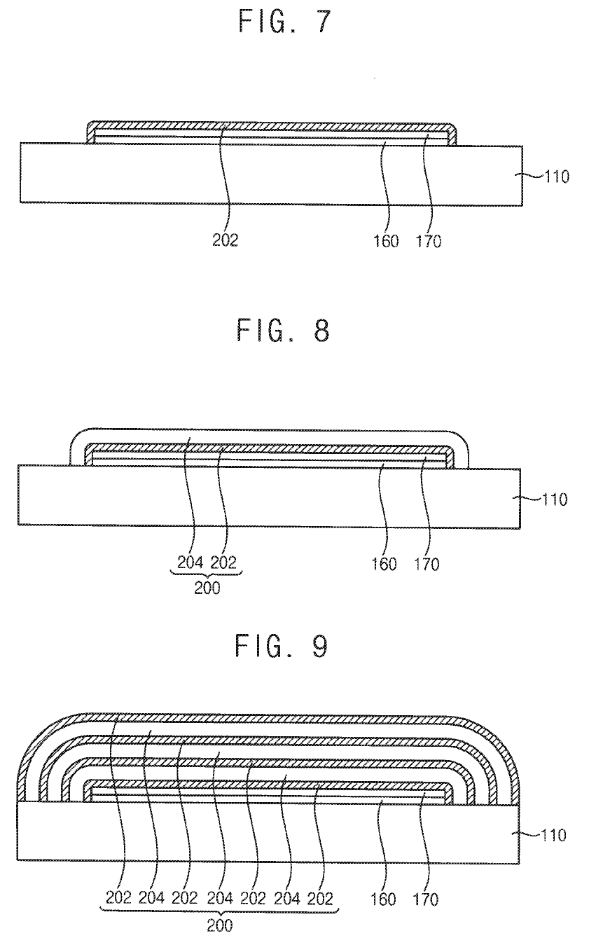

Referring to FIGS. 7 to 10, a thin film encapsulation layer 200 may be formed on the base substrate 110 to cover the organic light emitting display element 170.

The thin film encapsulation layer 200 may include inorganic layers 202 and organic layers 204 stacked on each other. For example, the inorganic layer 202 and the organic layer 204 may form one sub-encapsulation layer, and the thin film encapsulation layer 200 may include at least two sub-encapsulation layers.

First, as illustrated in FIGS. 1, 4 and 7, the substrate including the organic light emitting display element 170 formed thereon may be loaded into a chamber 10 of the plasma processing apparatus in FIG. 1, and then, a plasma deposition process may be performed on the base substrate 110 to form the inorganic layer 202 on the base substrate 110.

The inorganic layer 202 may be formed by a plasma-enhanced chemical vapor deposition process. For example, the inorganic layer 202 may include silicon oxide, silicon nitride, copper oxide, iron oxide, titanium oxide, zinc selenide, aluminum oxide, etc.

Then, as illustrated in FIG. 8, an organic layer 204 may be formed on the base substrate 110 including the inorganic layer 202 formed thereon, and then another inorganic layer 202 may be formed on the organic layer 204.

In particular, the base substrate 110, including the inorganic layer 202 formed thereon, may be unloaded from the chamber 10 in FIG. 1, and then transferred to an organic deposition apparatus for performing an organic layer deposition process.

The organic layer 204 may be formed by a spin coating process, a printing process, a chemical vapor deposition process, etc. For example, the organic layer 204 may include an epoxy resin, acrylate resin, urethane resin, etc.

The base substrate 110, including the organic layer 204 formed thereon, may be unloaded from the organic deposition apparatus, and then transferred to the chamber 10 of the plasma processing apparatus in FIG. 1 such that a plasma deposition process may be performed on the base substrate 110 to form another inorganic layer 202 on the base substrate 110.

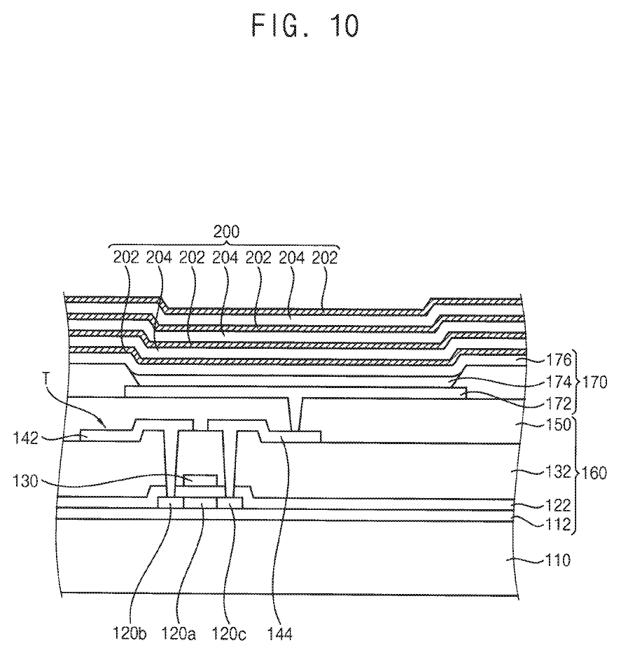

As illustrated in FIGS. 9 and 10, the thin film encapsulation layer 200, including the inorganic layers 202 and the organic layers 204 alternately stacked on each other, may be formed on the base substrate 110 to cover the organic light emitting display element 170.

The inorganic layer 202 may be thinner than the organic layer 204. For example, the inorganic layer 202 may have a thickness of about 100 nm, and the organic layer 204 may have a thickness of about 500 nm.

The thin film encapsulation layer 200 of the organic light emitting display device 100 may relieve or distribute a stress generated when the substrate 110 is bent. The thin film encapsulation layer 200 may include a plurality of the organic layers and the inorganic layers to prevent oxygen or moisture from penetrating into the organic light emitting display element 170.

In exemplary embodiments, the plasma deposition apparatus 1 in FIG. 1 may be used to form the inorganic layers 202 of the thin film encapsulation layer 200. A thermal control unit 80 of the plasma deposition apparatus circulates a heat transfer medium through a first fluid passage 60 provided in a lower electrode 22 and a second fluid passage 70 provided in an upper electrode 30 to maintain the lower and upper electrodes 22 and 30 at the same temperature.

Accordingly, when the inorganic layers 202 of the thin film encapsulation layer 200 for protecting the organic light emitting display element 170 are formed, the lower and upper electrodes 22 and 30 may be adjusted to a desired temperature to avoid a temperature deviation of the substrate and reduce a control time for adjusting the temperature of the substrate, thereby improving productivity. Further, the temperature of the chamber 10 may be maintained at a desired temperature, thereby improving reliability of an organic light emitting display panel and extending lifetime of a gas distribution plate as a shower head.

According to exemplary embodiments of the present invention, a plasma deposition apparatus may be used to form an inorganic layer of an organic light emitting display panel. A thermal control unit of the plasma deposition apparatus may circulate a heat transfer medium through a first fluid passage provided in a first electrode and a second fluid passage provided in a second electrode to maintain the first and second electrodes at the same temperature.

Accordingly, when the inorganic layer of a thin film encapsulation layer for protecting an organic light emitting display element is formed on a substrate, the first and second electrodes may be adjusted to a desired temperature to avoid a temperature deviation of the substrate and reduce a control time for adjusting the temperature of the substrate, thereby improving productivity.

Further, the temperature of the chamber of the plasma deposition apparatus may be maintained at a desired temperature, thereby improving reliability of the organic light emitting display panel and extending lifetime of a gas distribution plate as a shower head.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A plasma processing method, comprising:
loading a substrate into a chamber of a plasma processing apparatus, the plasma processing apparatus comprising the chamber, a substrate stage configured to support the substrate and comprising a first electrode, and an opposing second electrode disposed on an upper portion of the chamber;
introducing a process gas into the chamber and onto the substrate;
applying first and second radio frequency signals respectively to the first and second electrodes to perform a plasma process on the substrate; and
maintaining the first and second electrodes at substantially the same temperature.

2. The method of claim 1, wherein maintaining the first and second electrodes at the same temperature comprises circulating a heat transfer medium through a first fluid passage disposed within the first electrode and a second fluid passage disposed on the second electrode.

3. The method of claim 2, wherein circulating the heat transfer medium comprises transferring heat from the heat transfer medium using a heat exchanger disposed in a circulation line connected to the first and second fluid passages.

4. The method of claim 3, wherein circulating the heat transfer medium further comprises heating the heat transfer medium using a heater disposed in the circulation line.

5. The method of claim 1, wherein maintaining the first and second electrodes at the same temperature comprises maintaining the first and second electrodes at a temperature of less than about 100° C.

6. The method of claim 1, further comprising comparing the temperature of the first and second electrodes.

7. The method of claim 1, wherein the substrate comprises a base substrate comprising an organic light emitting display element formed thereon, and the process gas comprises a depositing material for forming an inorganic layer on the substrate.

8. The method of claim 7, wherein the inorganic layer comprises silicon oxide or silicon nitride.

9. The method of claim 1, wherein the first fluid passage is disposed within the first electrode, and the second fluid passage is disposed on an outer surface of the second electrode.

10. The method of claim 1, further comprising exhausting a gas from the chamber to reduce the pressure inside of the chamber to a pre-selected vacuum level.
